(19) United States
(12) Patent Application Publication
(10) Pub. No.: US 2010/0255263 A1
(43) Pub. Date: Oct. 7, 2010

(54) GAS BARRIER FILM AND PROCESS FOR PREPARATION OF THE SAME

(75) Inventors: Toshiyuki Miyadera, Saitama (JP); Isamu Oshita, Saitama (JP); Soh Fujimura, Saitama (JP)

Correspondence Address: DRINKER BIDDLE & REATH (DC), 1500 K STREET, N.W., SUITE 1100, WASHINGTON, DC, 20005-1209, US

(73) Assignee: Pioneer Corporation, Meguro-ku (JP)

(21) Appl. No.: 12/438,645

(22) PCT Filed: Aug. 23, 2007
(86) PCT No.: PCT/JP2007/066347

§ 371 Date: Feb. 24, 2009

(30) Foreign Application Priority Data
Aug. 29, 2006 (JP) 2006-231945

(51) Int. Cl. B32B 3/30; B05D 1/36

(52) U.S. Cl. 428/172; 427/264

(57) ABSTRACT

Disclosed is a gas barrier film for preventing penetration of gas or moisture or the like. Such a gas barrier film includes a substrate and a gas barrier layer, which is formed on at least one main face of the substrate and has a recess part, wherein an embedment part is formed by charging a filler into the recess part. The embedment part is completed by forming the embedment layer made of the filler on the gas barrier layer having the recess part, and depositing the filler in the recess part of the gas barrier layer while contacting the embedment layer with a cleaning device to expand and remove the embedment layer.

### TECHNICAL FIELD

The present invention relates to a gas barrier film and a process for preparation of the same.

### BACKGROUND ART

A flexible organic EL display panel with fabricated by forming a plurality of organic EL devices on a resin substrate has been developed. Such a resin substrate may be formed using synthetic resin, plastic, and the like. An organic EL device means a self-light emitting device which includes at least one organic thin film having a fluorescent layer consisting of an organic compound to exhibit electro-luminescence (hereinafter, referred to as “EL”) emitted by current input, between an anode and a cathode.

When a device vulnerable to oxygen or moisture such as an organic EL device is fabricated on a plastic substrate, an inorganic gas barrier layer such as silicon oxide or the like must be formed on a resin substrate to protect the device. Moreover, there is a strong requirement for a gas barrier film with excellent gas barrier properties suitable for a resin substrate.

However, the formed inorganic gas barrier layer generally has a recess part as defects, for example, through-holes or pin-holes or the like in the range of micrometers, thus not preventing deterioration of a device due to gas penetration through the defects.

Since the inorganic gas barrier layer is known to have defects in the range of micrometers, the gas barrier layer is often fabricated in the form of a multi-layered film by interposing an alternative layer between the gas barrier layers so as to fill the defects which in turn delays gas penetration through the defects.

As for a film having such a gas barrier layer fabricated according to a conventional method, the film is directly used as a device substrate even if the film contains defects in the gas barrier layer. Alternatively, in order to improve gas barrier properties, a plurality of gas barrier layers are laminated by interposing an intermediate layer or the like therebetween, wherein defects present in each of the layers are in the range of micrometers and substantially identical to those of a single layer film.

The gas barrier layer known in the prior art generally has defects in the range of micrometers and cannot prevent gas penetration through the defects. For example, even for a gas barrier layer in a multi-layered laminate form, it is impossible to improve defects in each layer. Instead, since positions of defects in the layers are spaced apart from one another, applying such a structural feature may only delay a time of gas penetration (see Patent Literature).

### [Patent Literature] Japanese Laid-Open Patent Application No. 2003-282239

### DISCLOSURE OF THE INVENTION

### Problem to be Solved by the Invention

Therefore, the present invention has been made in view of the above problems, and it is an object of the present invention to provide a gas barrier film for preventing penetration of gas such as oxygen or the like and/or moisture or the like.

### Means for Solving the Problem

As an exemplary embodiment of the present invention to accomplish the above object, there is provided a gas barrier film comprising: a substrate; and a gas barrier layer, which is formed on at least one main face of the substrate and has a recess part; the gas barrier film being characterized by further comprising an embedment part which is formed by charging a filler into the recess part.

Another exemplary embodiment of the present invention is a process for preparation of a gas barrier film including a substrate and a gas barrier layer, which is formed on at least one main face of the substrate and has a recess part, the process comprising:
forming the gas barrier layer having the recess part on the face of the substrate;
forming an embedment layer made of a filler on the gas barrier layer having the recess part; and
depositing the filler in the recess part of the gas barrier layer while contacting the embedment layer with a cleaning device to expand and remove the embedment layer, so as to form an embedment part.

According to the above configuration of the present invention, defects (in the recess part) in the range of micrometers generated in the step of forming the gas barrier layer may become the embedment part itself by charging the same or other materials into the recess part. Cavities of the recess part of the gas barrier layer may be coated with a liquid material, although it is less than expectable to exhibit superior gas barrier properties endowed by the coated liquid material itself. That is, since other parts except the recess part are also coated by the liquid filler, the gas barrier properties may be somewhat deteriorated. On the contrary, the present invention applies desired filler, for example, a metal substance having excellent gas barrier properties and capable of being placed only in the recess part, thereby favorably improving gas barrier properties of a gas barrier layer.

### BRIEF DESCRIPTION OF THE DRAWINGS

FIG. 1 is a schematic partial cross sectional view illustrating a gas barrier film according to an exemplary embodiment of the present invention;

FIG. 2 is a schematic partial cross sectional view illustrating a plastic substrate to explain a process for preparation of a gas barrier film according to an exemplary embodiment of the present invention;

FIG. 3 is a schematic partial cross sectional view illustrating the plastic substrate to explain the process for preparation of a gas barrier film according to the exemplary embodiment of the present invention;

FIG. 4 is a schematic partial cross sectional view illustrating the plastic substrate to explain the process for preparation of a gas barrier film according to the exemplary embodiment of the present invention;

FIG. 5 is a schematic partial cross sectional view illustrating a gas barrier film according to another exemplary embodiment of the present invention;

FIG. 6 is a schematic partial cross sectional view illustrating a gas barrier film according to another exemplary embodiment of the present invention; and

FIG. 7 is a schematic partial cross sectional view illustrating a gas barrier film according to another exemplary embodiment of the present invention.

### EXPLANATION OF REFERENCE NUMERALS

PH recess part
11 substrate
12 gas barrier layer
13 embedment layer
20 cleaning device
111 planar layer
131 embedment part

### DETAILED DESCRIPTION OF THE INVENTION

Hereinafter, the following description will be given of an organic EL device and a process for fabrication thereof according to exemplary embodiments of the present invention with reference to the accompanying drawings.

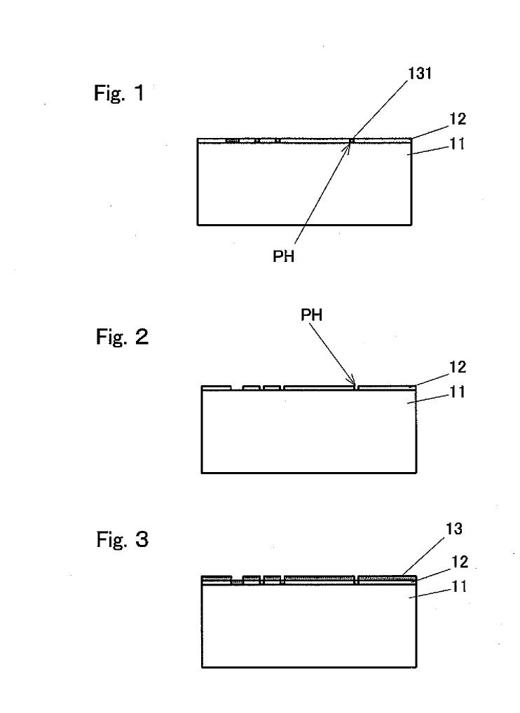

FIG. 1 is a partially enlarged cross sectional view illustrating a gas barrier film.

The gas barrier film according to an exemplary embodiment of the present invention includes a substrate 11 and a gas barrier layer 12 having a pin-hole type recess part (hereinafter referred to as “PH”) which is formed on at least one main face of the substrate, wherein an embedment part 131 is formed by charging a filler in the recess part PH.

Such filler may include some substances different from a raw material for the gas barrier layer, for example, metals, metal oxides, metal nitrides, resins, etc., or otherwise, may be the same materials as that of the gas barrier layer. In view of functional effects for coating the recess part, substances having ductile properties such as metals are more preferred. Metal oxides and/or nitrides may sometimes exhibit superior gas barrier properties over pure metals. However, such metal oxides or nitrides lack ductile properties and are difficult to favorably coat the recess part. For this reason, after a coating process is conducted using a metal substance, a finishing process such as oxidation or nitrification is performed to enhance gas barrier properties, thereby forming a coated part with high defect-coating efficiency as well as excellent gas barrier properties.

As to preparation of a gas barrier film, a thin layer made of the filler formed on a gas barrier layer may be expanded and removed by a chemical mechanical polishing method (CMP) or a mechanical process such as tape lapping (polishing), roll polishing, and the like, while depositing the filler only in a recess part of the gas barrier layer.

First of all, according to any conventional method including, for example, a dry method for film formation such as sputtering, vacuum vapor deposition, chemical vapor deposition (CVD), and the like. and a wet method for film formation such as printing, spin-coating and the like, a gas barrier layer is formed on a substrate. Next, a metal layer made of a filler is laminated on the gas barrier layer. Following this, the CMP process or the like is performed to expand and remove the metal layer. In the case of using a dry type film formation method such as vapor deposition or the like, since a recess part present in the metal layer is also reflected in an upper layer thereof, the metal layer cannot sufficiently coat a recess part of the gas barrier layer. Conversely, the CMP process may remove the metal layer while elongating the same and, as a result, a metal fraction is charged only into the recess part of the gas barrier layer.

As such, according to an exemplary embodiment of the present invention, the recess part of the gas barrier layer is coated by a filler different from (or identical to) a raw material for the gas barrier layer so as to considerably reduce gas penetration through the same. Moreover, a smooth gas barrier surface can be obtained owing to polishing effects by a mechanical process and, in addition, defects of electrodes or thin film devices (i.e., circuit between electrodes or the like) arranged on the gas barrier surface may be reduced.

Repeating the above processes to the substrate 11, a multi-layered gas barrier layer having an embedment part may be successfully prepared.

The gas barrier layer may comprise, for example, silicon nitride oxide, silicon oxide, silicon carbide, silicon carbide oxide, alumina, titanium oxide, titanium nitride, and so forth.

The substrate may be fabricated using any plastic film such as polyethylene terephthalate, polyethylene-2,6-naphthalate, polycarbonate, polysulfone, polyethersulfone, polyetheretherketone, polyphenoxyether, polyarylate, fluorine resin, polypropylene, polyethylene naphthalate, polyolefin, and so forth.

Alternatively, the substrate may be fabricated using a desired substance with improved strength, which comprises an aggregate type material such as glass fiber or the like combined with a plastic material, for example, a fiber reinforced plastic (FRP). The substrate may also be fabricated using a composite material comprising a plastic material with low elasticity and an additional material with high elasticity. Other than the glass fiber, some reinforced materials such as carbon fiber reinforced polymer (CFRP), aromatic polyamide fiber, and the like may also be used. For a base material, that is, a matrix, various resins such as thermo-curable resins, e.g., unsaturated polyesters, epoxy resin, polyamide resin, phenol resin and the like may be used. A fiber reinforced thermo plastic (FRTP) using a thermoplastic resin such as methyl methacrylate or the like may also be used. A process for fabrication of the substrate may include, for example: an SMC pressing method or the like wherein a sheet form compound comprising a pre-fabricated aggregate material combined with a resin is compressed and molded in a mold; a Hand lay-up method or Splay-up method or the like wherein fiber materials are placed in a mold to laminate multiple layers while defoaming a resin composite containing a hardening agent, and so forth.

Alternatively, the substrate may comprise a metal foil made of stainless steel or the like.

As described above, the substrate may be fabricated using a plastic substance, a plastic composite material comprising a plastic matrix and an additional material based on an organic or inorganic material different from the plastic matrix, or a metal foil, etc.

FIGS. 2 to 4 are each schematic partial cross sectional views illustrating a plastic substrate according to a process for preparation of a gas barrier film.

First of all, referring to FIG. 2, a gas barrier layer 12 made of silicon oxide is formed on a clean plastic substrate 11 by, for example, vacuum deposition. A recess part PH is present on a surface of the gas barrier layer 12.

Subsequently, as illustrated in FIG. 3, an embedment layer 13 is deposited in a desired thickness on the same surface of the gas barrier layer 12 on which the recess part PH is formed. On the surface of the embedment layer 13, uneven parts caused by other planar parts as well as the recess parts PH are formed. Such an embedment layer 13 may be formed using a desired substance including metals, for example, at least one selected from copper (Cu), aluminum (Al), tungsten (W), gold (Au), silver (Ag), silicon (Si), nickel (Ni), titanium (Ti), indium (In) and magnesium (Mg), or alloys, oxides, carbides or nitrides thereof or the like by any conventional method such as plating, CVD, PVD, sputtering and the like. For instance, in the case where an embedment part (that is, the embedment layer 13) comprises copper and the gas barrier layer 12 comprises silicon oxide, since copper has a diffusion coefficient higher than that of silicon oxide and is diffused better than silicon oxide, the embedment part can prevent gas penetration. Alternatively, the embedment layer 13 may also comprise the same material as the gas barrier layer 12.

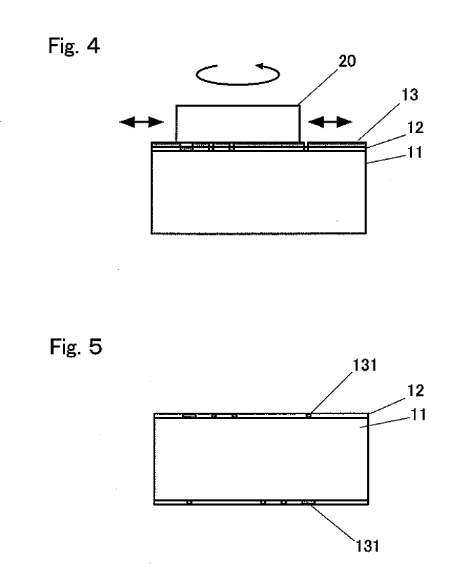

Referring to FIG. 4, excess of the embedment layer 13 on the gas barrier layer 12 is removed and smoothed by CMP to form an embedment part 131. More particularly, introducing a polishing solution (not shown) on a surface of the embedment layer 13 allows a cleaning device 20 to come into contact with a prominence part of the embedment layer 13, followed by relative displacement thereof, that is, cleaning the surface of the embedment layer 13 with the polishing solution by the cleaning device 20, so that the embedment layer 13 is selectively removed.

The cleaning device 20 may be, for example, in a round shape and may have a cleaning face to remove the embedment layer 13, which comes into contact with the embedment layer 13 of the plastic substrate 11 fixed on a flat-top support table (not shown). Such a cleaning device 20 may be fabricated of, for example, an elastic-plastic material, a soft brush type material, a sponge type material, a porous material and the like. For instance, a porous substance comprising a resin such as polyvinyl acetate (PVA), urethane foam, Teflon foam, Teflon fiber non-woven fabric, melamine resin, epoxy resin or the like is preferably used to fabricate the cleaning device 20.

Additionally, after the embedment layer 13 is removed via CMP, the plastic substrate 11 is washed in order to remove the polishing solution containing alumina particles or the like which was added during the CMP process and remained without polishing.

A supporting device for the cleaning device 20 turns the cleaning device 20 around a pre-determined rotational axis while pressing the cleaning device 20 to the embedment layer 13. In order to horizontally move the supporting device for the cleaning device 20 on a plane in parallel to a cleaning face of the cleaning device 20, a horizontal moving device is also provided to the supporting device. Using the supporting device, the cleaning device 20 relatively displaces to the surface of the embedment layer 13 while coming into contact with the same so that the surface of the embedment layer 13 may be uniformly expanded and removed. Although such relative displacement is carried out by rotating the cleaning device 20 around the rotational axis, a sheet type cleaning device 20 may also be used.

As is apparent from the above description, moving the surface of the embedment layer 13 relative to the cleaning device 20, the cleaning device 20 may clean and remove the embedment layer 13 so that a roughness of the surface of the embedment layer 13 may be efficiently reduced or smoothed even with reduced pressing force.

FIG. 5 illustrates a gas barrier film prepared according to another exemplary embodiment of the present invention. As for such gas barrier film, a gas barrier layer 12 is formed on each of top and bottom faces of a plastic substrate 11 so as to more considerably reduce an amount of gas penetrating through the plastic substrate 11 and/or a gas penetration rate. In addition, it is possible to decrease adverse effects caused by difference in characteristics between the plastic substrate 11 and the gas barrier layer 12.

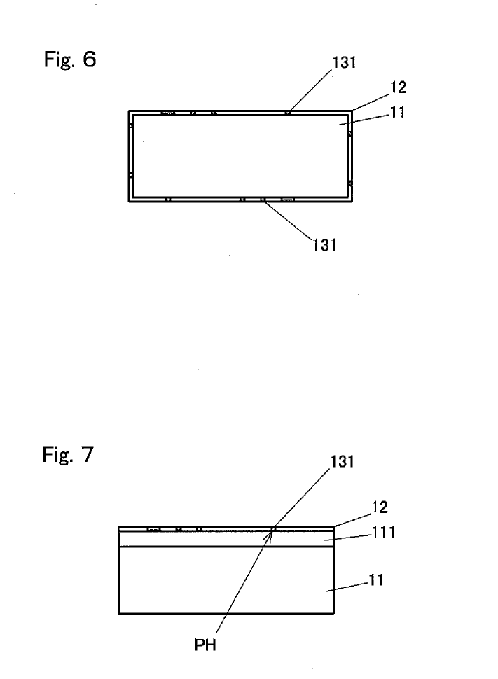

FIG. 6 illustrates a gas barrier film prepared according to a further exemplary embodiment of the present invention. As for such gas barrier film, a gas barrier layer 12 is formed around peripheral sides of a plastic substrate 11 so as to inhibit gas penetration through the peripheral sides of the plastic substrate 11. In addition, it is possible to inhibit size alteration and/or optical variations or the like caused by moisture absorption of the plastic substrate 11.

FIG. 7 illustrates a gas barrier film prepared according to yet another exemplary embodiment of the present invention. As for such gas barrier film, a planar layer 111 is formed throughout the surface of a pre-fabricated plastic substrate 11 and a gas barrier layer 12 is formed on the surface of the pre-fabricated plastic substrate 11 so as to more efficiently inhibit gas penetration. In addition, it is possible to interpose the planar layer 111 between the gas barrier layer 12, which was formed on each of top and bottom faces or around peripheral sides of the substrate 11 as described in the former two embodiments, and the plastic substrate 11. As for this exemplary embodiment, the substrate may comprise a metal foil made of stainless steel or the like. In this case, the planar layer 111 may be prepared using an insulation material.

1. A gas barrier film comprising: a substrate; and a gas barrier layer, which is formed on at least one main face of the substrate and has a recess part; the gas barrier film being characterized by further comprising an embedment part which is formed by charging a filler into the recess part.

2. The gas barrier film according to claim 1, wherein the substrate is fabricated using a plastic substance, a plastic composite material comprising a plastic matrix and an additional material based on an organic or inorganic material different from the plastic matrix, or a metal foil.

3. The gas barrier film according to claim 1 or 2, wherein the filler comprises a material different from a raw material for the gas barrier layer.

4. The gas barrier film according to claim 1 or 2, wherein the filler comprises the same material as that of the gas barrier layer.

5. The gas barrier film according to claim 1, wherein the gas barrier layer is a multi-layered film.

6. The gas barrier film according to claim 5, wherein the substrate is fabricated using a plastic substance, a plastic composite material comprising a plastic matrix and an additional material based on an organic or inorganic material different from the plastic matrix, or a metal foil.

7. The gas barrier film according to claim 5 or 6, wherein the filler comprises a material different from a raw material for the gas barrier layer.

8. The gas barrier film according to claim 5 or 6, wherein the filler comprises the same material as that of the gas barrier layer.

9. A process for preparation of a gas barrier film including a substrate and a gas barrier layer, which is formed on at least one main face of the substrate and has a recess part, the process comprising:
forming the gas barrier layer having the recess part on the face of the substrate;
forming an embedment layer made of a filler on the gas barrier layer having the recess part; and
depositing the filler in the recess part of the gas barrier layer while contacting the embedment layer with a cleaning device to expand and remove the embedment layer, so as to form an embedment part.

10. The process according to claim 9, wherein the filler comprises a material different from a raw material for the gas barrier layer.

11. The process according to claim 9, wherein the filler comprises the same material as that of the gas barrier layer.

12. A process for preparation of a gas barrier film including a substrate and a gas barrier layer, which is formed on at least one main face of the substrate and has a recess part, the process comprising:
forming the gas barrier layer having the recess part on the face of the substrate;
forming an embedment layer made of a filler on the gas barrier layer having the recess part;
depositing the filler in the recess part of the gas barrier layer while contacting the embedment layer with a cleaning device to expand and remove the embedment layer, so as to form an embedment part; and
conducting oxidation or nitrification or the like as a finishing process after forming the embedment part.

13. The process according to claim 12, wherein the filler comprises a material different from a raw material for the gas barrier layer.

14. The process according to claim 12, wherein the filler comprises the same material as that of the gas barrier layer.
